(19) United States
(12) Patent Application Publication
(10) Pub. No.: US 2017/0167120 A1
(43) Pub. Date: Jun. 15, 2017

(54) Thermo Water

(71) Applicant: Mahmut Sarikaya, Washington, DC (US)

(72) Inventor: Mahmut Sarikaya, Washington, DC (US)

(21) Appl. No.: 15/379,476

(22) Filed: Dec. 14, 2016

Related U.S. Application Data
(60) Provisional application No. 62/386,904, filed on Dec. 15, 2015.

(51) Int. Cl. E03B 3/28; H01L 35/28; F24F 3/14; F25B 21/04; C02F 1/32; C02F 1/44; C02F 1/00; B01D 46/00; E03B 11/10; B01D 5/00

(52) U.S. Cl. CPC E03B 3/28; E03B 11/10; H01L 35/28; F24F 3/1405; B01D 5/0027; B01D 5/0072; B01D 5/009; B01D 5/0042; C02F 1/325; C02F 1/441; C02F 1/001; B01D 46/0032; F25B 21/04; C02F 2303/04; C02F 2201/009

(57) ABSTRACT

A water supply system is provided including an air suction device for pulling in air from a surrounding area, an air humidity condensing system for transforming humidity contained in the pulled in air into water, a water collector for collecting the water generated by the air humidity condensing system, a water treatment system for filtering and disinfecting the collected water, and a water storage tank for storing the treated water. The water supply system can further include a power supply system for supplying power needed to operate the water supply system. The power supply system can include a solar power supply system and/or a thermoelectric power supply system.

### CROSS-REFERENCE TO RELATED APPLICATION

This application claims the benefit of co-pending U.S. Provisional Patent Application Ser. No. 62/386,904 filed Dec. 15, 2015, which is incorporated herein in its entirety.

### FIELD OF THE INVENTION

The present invention relates generally to water supply systems, and more particularly, to a water supply system that supplies water utilizing air humidity and nature and/or alternative energy sources.

### BACKGROUND OF THE INVENTION

There are areas where humidity is high and yet a water supply is scarce. Dehumidifiers can be used in these areas to remove humidity from the air. A dehumidifier typically includes a fan that pulls in air from the surrounding area, which typically has a high moisture level. As the air passes through the dehumidifier, it comes into contact with the dehumidifier's cooling coils, which use condensation to pull moisture from the air by lowering the temperature. This de-moisturized air is then reheated and redistributed back into the room—this time without all the moisture. The collected moisture remains on the coils and drips into a reservoir which will then be emptied regularly or drained automatically. It is wasteful, especially in the water scarce areas, to let the moisture water collected by the dehumidifiers to be simply dumped or drained away without being utilized.

In certain areas, severe water shortages not only perpetuate the cycle of poverty and misery, but can also lead to malnutrition, even death. More water would allow more crops to be grown and more food on the table for those that need it most. A water supply system can be utilized to turn the moisture collected by a dehumidifier into usable water. However, a water supply system of this kind needs an electric power supply to operate and would not be practical in the areas where electricity is not available or is very limited and expensive.

Accordingly, there is an established need for a water supply system that can turn air humidity into usable water supply and can be powered by nature and/or alternative energy sources such as solar energy or heat energy to provide usable water in areas where both water supply and electricity supply are scarce.

### SUMMARY OF THE INVENTION

The present invention is directed to a practical and cost effective water supply system that is capable of turning air humidity into a fresh clean water supply and being powered by nature and/or alternative energy sources. The water supply system can include an air suction device for pulling in air from the surrounding area, an air humidity condensing system that transforms humidity in the pulled in air into water, a water collector for collecting the water generated by the air humidity condensing system, a water treatment system for filtering and disinfecting the collected water, and a water storage tank for storing the treated water. A solar power generator and/or a thermoelectric generator (TEG) can be used to provide the power needed by the water supply system.

Introducing a first embodiment of the invention, the present invention consists of a water supply system, comprising:
an air suction device for pulling in air from the surrounding area;
an air humidity condensing system that transforms humidity in the pulled-in air into water;
a water collector for collecting the water generated by the air humidity condensing system;
a water treatment system for filtering and disinfecting the collected water; and
a water storage tank for storing the treated water.

In another aspect, the water supply system further comprises:
a power supply system for supplying power needed to operate the water supply system.

In another aspect, the power supply system can include a solar power supply system.

In another aspect, the power supply system can include a thermoelectric power supply system.

In another aspect, the water supply system further comprises:
a housing for accommodating the water supply system.

In another aspect, the air suction device can be arranged in an upper part of the housing.

In another aspect, the air suction device can include at least one fan associated with a driving motor.

In another aspect, the air humidity condensing system can be mounted in the housing below the air suction device.

In another aspect, the air humidity condensing system can be a conventional dehumidifier or a humidity condensing installation specifically designed for the invention for using either outdoors or indoors.

In another aspect, the air humidity condensing system can include a compressor, a condenser, a control valve, and an evaporator connected to the compressor via a refrigerant pipe.

In another aspect, a thermoelectric cooler can be used as a cooling element in the air humidity condensing system.

In another aspect, the water collector can be arranged in the housing below the air humidity condensing system.

In another aspect, the water treatment system can be provided in the housing below the water collector.

In another aspect, the treated water coming out of the water treatment system can fall into or guided via a pipe to the water storage tank.

In another aspect, the solar power supply system can be mounted above the housing for absorbing energy from the sunlight and converting the absorbed solar energy into electric energy for use by the water supply system.

In another aspect, the absorbed energy can be stored in an energy storage unit, such as a rechargeable battery, and released at night or when the water supply system is to be actuated for condensing air humidity.

In another aspect, a thermoelectric generator can be connected to the condenser to generate thermoelectric power which can be stored in battery cells or a capacitor to accommodate outputs ranging from a 12-volt up to a 48-volt system, to recharge the original starting system, or providing optional AC input.

In another aspect, the water treatment system can include electro static filters for removing particles in the air.

In another aspect, the water treatment system can include further include a UV-RO (Reverse Osmosis) system for disinfecting the filtered water

Introducing another embodiment of the invention, the present invention consists of an energy and water supply system, comprising:
a water supply system including:
   an air suction device for pulling in air from the surrounding area;
   an air humidity condensing system that transforms humidity in the pulled-in air into water;
   a water collector for collecting the water generated by the air humidity condensing system;
   a water treatment system for filtering and disinfecting the collected water; and
   a water storage tank for storing the treated water; and
an energy supply system connected to the water supply system.

In another aspect, the energy supply system provides electric power needed to operate the water supply system, and optionally supplies additional power for other purposes.

These and other objects, features, and advantages of the present invention will become more readily apparent from the attached drawings and the detailed description of the preferred embodiments, which follow.

### BRIEF DESCRIPTION OF THE DRAWINGS

The preferred embodiments of the invention will hereinafter be described in conjunction with the appended drawings provided to illustrate and not to limit the invention, where like designations denote like elements, and in which:

FIG. 1 presents a diagrammatic view of a thermoelectric generator;

FIG. 2 presents a schematic perspective view of a thermoelectric generator and a thermoelectric cooler;

FIG. 3 presents a schematic view of folding solar cells in connection with a system box;

FIG. 4 presents a perspective view of the system box shown in FIG. 3 for controlling the folding solar cells as shown in FIG. 3, the system box incorporating a water supply system of the present invention therein;

FIG. 5 presents a sectional view illustrating an evaporator inside a heat sink;

FIG. 6 presents a top and side view of the thermoelectric generator to be connected to the condenser shown in FIG. 5;

FIG. 7 presents a diagrammatic view illustrating the process of harnessing condenser heat to electrical output in the overall system configuration;

FIG. 8 presents a diagrammatic view of an exemplary condenser configuration;

FIG. 9 presents a diagrammatic view illustrating the water flow; and

FIG. 10 presents a diagrammatic view illustrating an exemplary water supply system utilizing solar energy.

Like reference numerals refer to like parts throughout the several views of the drawings.

### DETAILED DESCRIPTION

The following detailed description is merely exemplary in nature and is not intended to limit the described embodiments or the application and uses of the described embodiments. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims.

It is also to be understood that the specific devices and processes illustrated in the attached drawings, and described in the following specification, are simply exemplary embodiments of the inventive concepts defined in the appended claims. Hence, specific dimensions and other physical characteristics relating to the embodiments disclosed herein are not to be considered as limiting, unless the claims expressly state otherwise.

Shown throughout the figures, the present invention is directed toward a practical and cost effective water supply system that is capable of turning air humidity into fresh clean water supply and being powered by nature and/or alternative energy sources

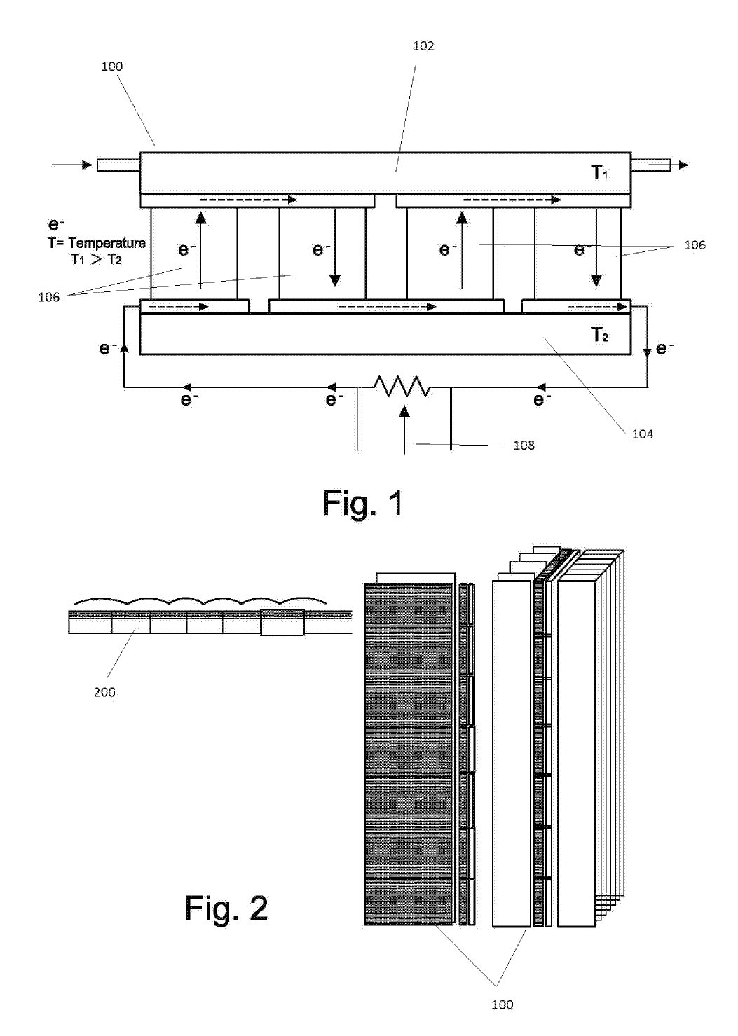

Referring now to FIG. 1, a thermoelectric generator (TEG) 100 is diagrammatically illustrated. As shown, the TEG 100 includes a hot side 102 having a temperature T₁, a cold side 104 having a temperature T₂, and thermostatic materials 106 arranged between the hot side 102 and the cold side 104. The temperature T₁ needs to be substantially higher than the temperature T₂ to maintain a large temperature gradient to generate electricity. The thermostatic materials 106 have both high electrical conductivity and low thermal conductivity, and are connected electrically in series, but thermally in parallel. The TEG 100 takes in heat from a heat source such as a condenser and outputs electricity to an output terminal 108. Multiple TEG devices can be connected in series, and with each TEG generating power, there is a combined output. The entire device, including the condenser coil, can be scaled in size to accommodate industry needs and specifications. The energy generated from the condenser can be stored in battery cells or a capacitor configuration to accommodate outputs ranging from a 12-volt up to a 48-volt system, to recharge the original starting system, or to provide optional AC output.

FIG. 2 shows an exemplary thermoelectric generator 100 and an exemplary thermoelectric cooler 200. The thermoelectric cooler 200 and the thermoelectric generator 100 can be used in night operation to improve overall system efficiency. The thermoelectric cooler elements are energized with a direct current signal that is effective to cool the cold plate to a predetermined temperature. Moisture in the air condenses on the cold plate and travels to the reservoir. The thermoelectric generator 100 can be connected to the hot plate of the thermoelectric cooler to act as a heat sink for extracting energy from the thermoelectric cooler system.

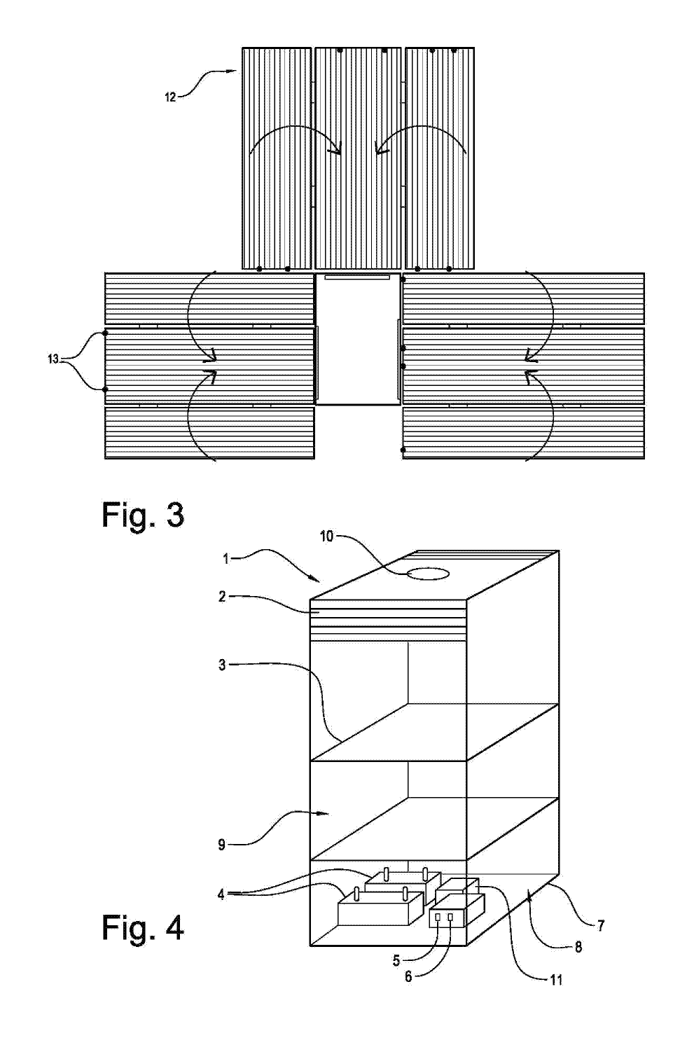

Referring now to FIG. 3, folding solar panels 12 are illustrated in connection with a system box 1 in which the water supply system of the present invention is located. The solar panels collect solar energy and generate electrical energy through an inverter electrically connected to the storage battery for providing DC to AC power conversion. A solar panel assembly is electrically connected to the power adapter where the assembly provides power to the power adapter for use in charging the storage battery and delivering power to the one or more outputs.

FIG. 4 illustrates the system box 1 in more detail. As shown, the system box 1 includes an air vent 2, a shelf 3, a battery 4, an inverter 5, a battery charger 6, an optional AC outlet 7, a compressor 8, a door 9, a sink 10 and a solar connector 11. The system box or casing 1 can have four sections. A top section can hold the evaporator coil, the condenser coil, the thermoelectric generator TEG, the thermoelectric cooler TEC, and the system fan. A second section can store the water reservoir and the RO filtration system. A third section can hold the water chiller, the water heater, and the water storage. The bottom section is for the battery, the charger, the controller's compressor and the inverter. Vertical frame can be comprised of a pair of spaced flat structural members arranged in spaced relation with a flat structural member secured between the ends of the parallel members, which typically are sheet metal panels, forming the internal wall of each of the four compartments and extending upwardly from the floor which is secured to a base comprised of a plurality of channel secured together. The external walls of the compartments can be constructed of formed sheet metal panels which are placed around the internal walls. Each of these panels forms a corner and adjoining side panels of the cabinet frame at the base and extends through the top of the cabinet to be grasped by a hand, if desired. Doors can be provided so that the compartments can be readily accessible from the outwardly facing sides of the cabinet.

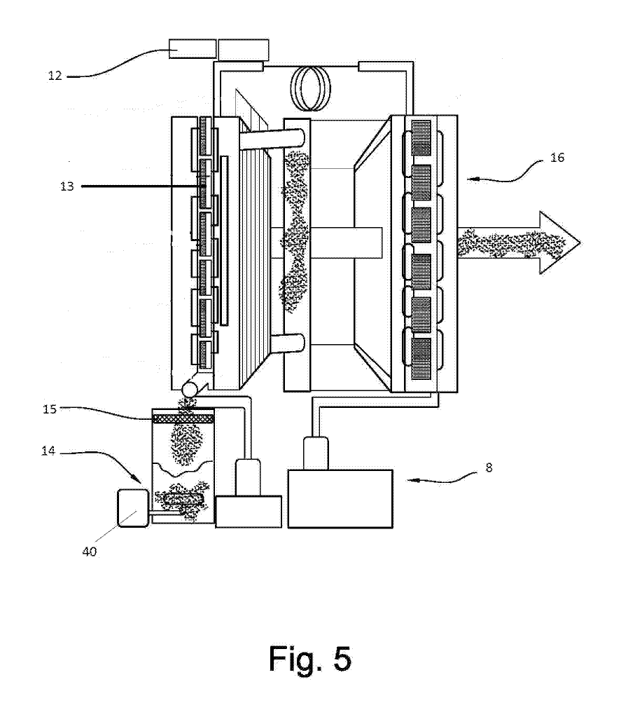

Referring now to FIG. 5, the water condensation process and the energy generation process is illustrated. As shown, humidity-rich air is drawn into the system through air-suction device 12 and is guided into the air humidity condensing system 13 where humidity in the air is condensed to water droplets that attach to the evaporator. When the droplets attached to the evaporator accumulate to a considerable amount, they form larger drops that fall into a water collector 14 provided below the air humidity condensing system 13. A filtrating means 15 is provided to strain articles from water collected as to produce purified water. An ozone generator 40 can provides ozone to the water to disinfect the water. The purified and disinfected water coming out of the water filtration and disinfection system can directly fall into or be guided via a pipe to a water storage tank and is stored therein for use.

The heat of the condenser 16 can be used in energy generation process. The gas, which flows through the condenser gas passageway may flow in opposite directions, and in this process, the high-temperature condenser gas pipe configured as flat not round integrally formed to be disposed sequentially in a parallel direction along the condenser pipe. In general, in a system depending on a running state of the system, warming up and heating steps for a system are performed when system initially starts, a thermoelectric power generating step is performed when the system runs, and a bypassing step is performed when the temperature of the condenser is raised to a predetermined temperature using a thermostat which raises a temperature of the gas when the system initially starts. The system should be warmed up while being operated to a particular temperature until energy generated. FIG. 5 shows the thermoelectric energy recovery, namely the compressor 8 being connected to the condenser coil 16 and the TEG being connected to the condenser coil 16 to generate electrical energy. The condenser coil 16 is connected to the evaporator coil 13 to generate water. A thermoelectric cooler can also be connected to the evaporator coil 13 to generate water for night operation. The heatsink can be connected to the hot side of the thermoelectric cooler to release heat. The heatsink can be connected to the thermoelectric cooler and the thermoelectric generator can be connected to the other side of the heat sink to recover energy from heatsink. The overall system can work with AC or DC configuration.

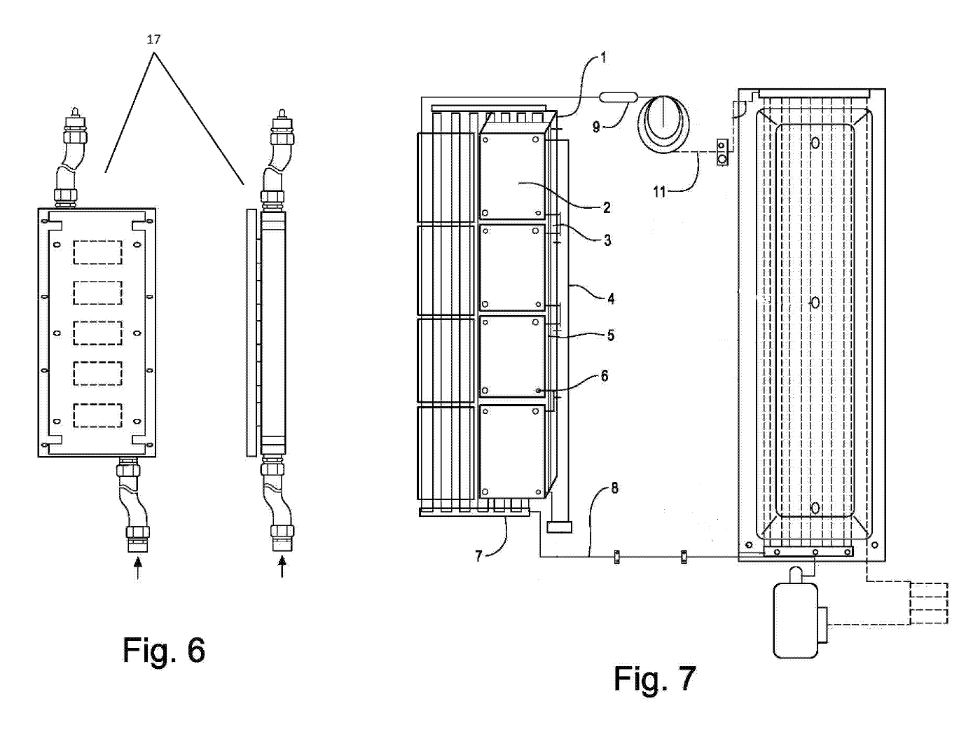

FIG. 6 is a top and side view of a thermoelectric generator 17 to be connected to the condenser coil 16 shown in FIG. 5. A thermoelectric power generating step is performed when the system runs, and a bypassing step is performed when the temperature of a condenser is raised to a predetermined temperature using a thermostat which raises a temperature of the gas when the system initially starts. FIG. 7 illustrates the process of harnessing condenser heat to electrical output in the overall system configuration.

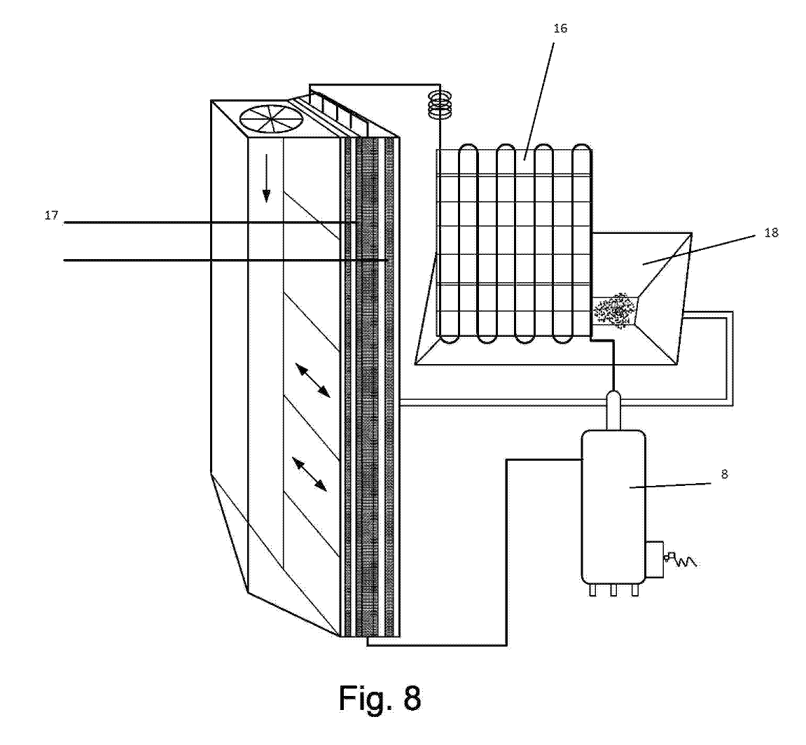

FIG. 8 illustrates an exemplary condenser configuration. As moisture is condensed from the air flow, it accumulates in the reservoir 18. A safety switch can be connected to the reservoir to prevent overflowing. Alternatively, an overflow hose may be provided to direct the excess moisture to a drain or pump the water to a water tank. When is system completely full, operation of the compressor for delivering hot compressed refrigerant is stopped. The thermoelectric generator 17 can be connected to the condenser 16 to turn waste heat into energy. At night time, the thermoelectric cooler is running not the compressor.

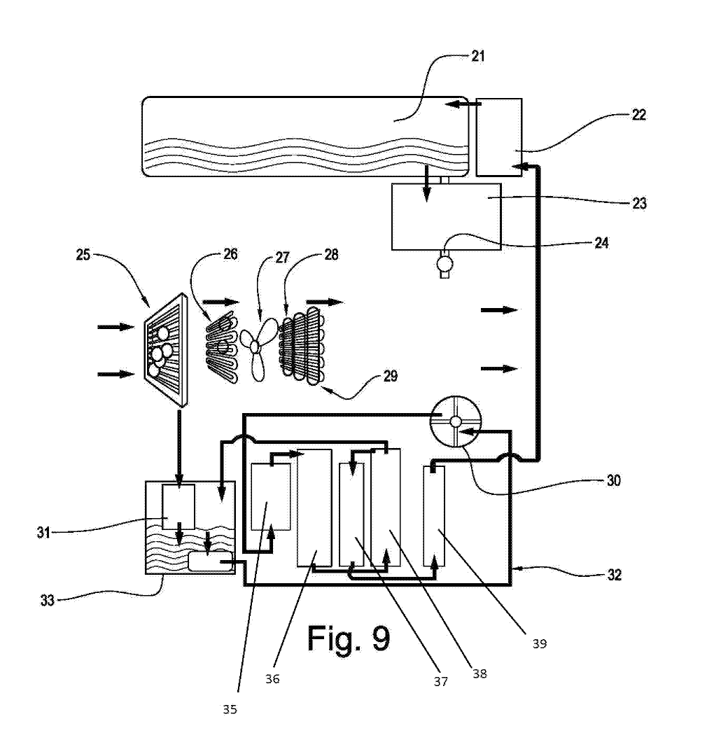

FIG. 9 illustrates an exemplary overall system showing the air circulation and water collection, filtration, and sanitation process. As shown, air is being pulled in through an air suction device 25 including a fan 27 and then comes into contact with the air humidity condensing system 26 where the humidity contained in the air is transformed into water which is collected in the water collector 33. The de-moisturized air is then redistributed back into the environment through the device 29. The water enters the water collector 33 through a filter 31 and then being further treated by the water treatment system 32 including, for example, a nanometer photocatalysis carbon filter 35, a nanometer molecular sieve and nanometer photocatalysis carbon filter 36, a nanometer molecular sieve 37, a RO (Reverse Osmosis) system 38, and a UV light device 39. The water is being circulating through the water treatment system 32 by a pump 30. The treated water is then being pumped into the storage tank 21 through a carbon filter with sieve 22. The water in the water tank 21 can be delivered as running cold water 23 through a water valve 24.

The filter 31 can be an electrostatic filter for removing airborne particles. The particle-attracting properties of an electrostatic filter allow it to remove more of the large particles in the air. Filters protect air system from damage associated with particle buildup. Electrostatic filters also remove some of the small particles in the air that are under 1 micron in size. UV-RO system is a combination of the RO and UV system. The UV light will disinfect filtered water at normal flow rate, providing one of the safest filtering systems available. Bacteria, viruses, and other micro-organisms are destroyed by interfering with the DNA and RNA. RO-UV system provides safe, pure water using Reverse Osmosis technology. It uses no chemicals or electricity and provides premium water quality. RO-UV improves both the taste and quality of the water. It reduces objectionable odors and sediment. RO-UV also reduces the water contaminants that may be present in the air.

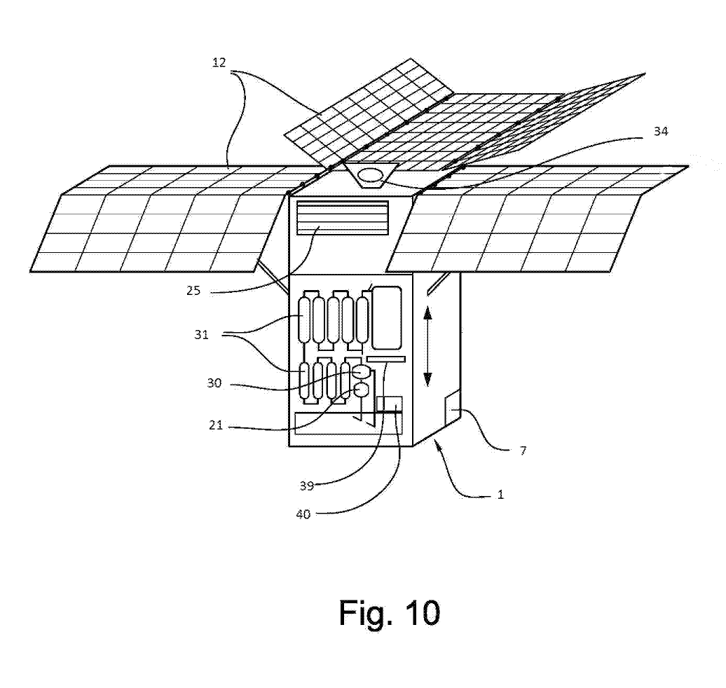

FIG. 10 illustrates an exemplary water supply system utilizing solar energy. The folding solar panels 12 provides solar energy for operating the water supply system inside the system box or casing 1. The folding solar panels 12 are designed to be portable and can be transported and installed anywhere. The solar panels can be installed above the system box or casing 1 for creating shade to protect the system box or casing 1 from the sun. The water supply system works indoor or outdoor with AC or DC current optional. As shown, the air enters the system through the air suction device 25, and leaves the system through an exit 34. Water collected from the humidity of the air can be pumped by a pump 30 through a filter 31 and being treated by UV light 39 and ozone generated by an ozone generator 40. The casing 1 has an optional AC/DC outlet 7.

Since many modifications, variations, and changes in detail can be made to the described preferred embodiments of the invention, it is intended that all matters in the foregoing description and shown in the accompanying drawings be interpreted as illustrative and not in a limiting sense. Thus, the scope of the invention should be determined by the appended claims and their legal equivalents.

What is claimed is:

1. A water supply system, comprising:
an air suction device for pulling in air from a surrounding area;
an air humidity condensing system for transforming humidity contained in the pulled-in air into water;
a water collector for collecting the water generated by the air humidity condensing system;
a water treatment system for filtering and disinfecting the collected water; and
a water storage tank for storing the treated water.

2. The water supply system as recited in claim 1, further comprising:
a power supply system for supplying power needed to operate the water supply system.

3. The water supply system as recited in claim 1, wherein the power supply system includes a solar power supply system and/or a thermoelectric power supply system.

4. The water supply system as recited in claim 1, wherein the water supply system further comprises:
a housing for accommodating the water supply system.

5. The water supply system as recited in claim 1, wherein the air suction device can be arranged in an upper part of the housing.

6. The water supply system as recited in claim 1, wherein the air suction device can include at least one fan associated with a driving motor.

7. The water supply system as recited in claim 1, wherein the air humidity condensing system can be mounted in the housing below the air suction device.

8. The water supply system as recited in claim 1, the air humidity condensing system can be a conventional dehumidifier or a humidity condensing installation specifically designed for the invention for using outdoors or indoors.

9. The water supply system as recited in claim 1, the air humidity condensing system can include a compressor, a condenser, a control valve, and an evaporator connected to the compressor via a refrigerant pipe.

10. The water supply system as recited in claim 1, wherein a thermoelectric cooler is used as a cooling element in the air humidity condensing system.

11. The water supply system as recited in claim 1, the water collector can be arranged in the housing below the air humidity condensing system.

12. The water supply system as recited in claim 1, the water treatment system can be provided in the housing below the water collector.

13. The water supply system as recited in claim 1, the treated water coming out of the water treatment system can fall into or guided via a pipe to the water storage tank.

14. The water supply system as recited in claim 3, the solar power supply system can be mounted above the housing for absorbing energy form the sunlight and converting the absorbed solar energy into electric energy for use by the water supply system.

15. The water supply system as recited in claim 14, the absorbed energy can be stored in an energy storage unit, and released at night or when the water supply system is to be actuated for condensing air humidity.

16. The water supply system as recited in claim 1, a thermoelectric generator can be connected to the condenser to generate thermoelectric power which can be stored in battery cells or a capacitor to accommodate from a 12-volt up to a 48-volt system, to recharge the original starting system, or providing optional AC input.

17. The water supply system as recited in claim 1, the water treatment system includes electro static filters for removing particles in the air.

18. The water supply system as recited in claim 1, the water treatment system further includes a UV-RO (Reverse Osmosis) system for disinfecting the filtered water.

19. An energy and water supply system, comprising:
a water supply system including:
an air suction device for pulling in air from the surrounding area;
an air humidity condensing system for transforming humidity contained in the pulled in air into water;
a water collector for collecting the water generated by the air humidity condensing system;
a water treatment system for filtering and disinfecting the collected water; and
a water storage tank for storing the treated water; and
an energy supply system connected to the water supply system.

20. The energy and water supply system as recited in claim 19, the energy supply system provides electric power needed to operate the water supply system, and supplies additional power for other purposes.
